(19) United States
(12) Patent Application Publication
(10) Pub. No.: US 2014/0000689 A1
(43) Pub. Date: Jan. 2, 2014

(54) NITRIDE SEMICONDUCTOR-BASED SOLAR CELL AND MANUFACTURING METHOD THEREOF

(71) Applicants: Dong Seon Lee, Gwangju (KR); Si Young Bae, Gwangju (KR); Do Hyung Kim, Gwangju (KR); Jong Hyeob Baek, Gwangju (KR); Seung-Jae Lee, Gwangju (KR)

(72) Inventors: Dong Seon Lee, Gwangju (KR); Si Young Bae, Gwangju (KR); Do Hyung Kim, Gwangju (KR); Jong Hyeob Baek, Gwangju (KR); Seung-Jae Lee, Gwangju (KR)

(21) Appl. No.: 14/003,899

(22) PCT Filed: May 17, 2011
(86) PCT No.: PCT/KR11/03650

§ 371 Date: Sep. 9, 2013

(30) Foreign Application Priority Data
Mar. 15, 2011 (KR) 10-2011-0022777

(51) Int. Cl. H01L 31/0236; H01L 31/18

(52) U.S. Cl. CPC H01L 31/02363; H01L 31/1856
USPC 136/255; 438/94

(57) ABSTRACT

Disclosed herein are a nitride semiconductor-based solar cell including a photoactive layer having a wide area for incident light and a manufacturing method thereof. Opening parts are formed in a mask layer partially shielding a first n-type nitride semiconductor layer. The first n-type nitride semiconductor layer is exposed through the opening part, and second n-type nitride semiconductor layers are grown based on the exposed first n-type nitride semiconductor layer. The grown second n-type nitride semiconductor layer is buried in the opening part and is formed in a hexagonal pyramid shape. In addition, a photoactive layer and a p-type nitride semiconductor layer are sequentially formed along the second n-type nitride semiconductor layer. Therefore, a hole injection-electron pair is easily formed by the incident light. Further, an area of the photoactive layer is increased, such that photoelectric conversion efficiency is improved.

### TECHNICAL FIELD

The present invention relates to a solar cell, and more particularly, to a solar cell including a nitride semiconductor grown on an intended region.

### BACKGROUND ART

A solar cell is a system directly converting solar energy into electrical energy using a photovoltaic effect. This photovoltaic power generation has advantages in that it does not require a fuel and does not cause thermal pollution and environmental pollution. However, it has disadvantages in that a high cost is required to generate electricity, such that an economical efficiency is low, and a power generation amount is limited due to a weather condition and a limited sunshine time.

A key point of a solar cell technology is to allow sunlight having energy larger than that of a forbidden band to be incident to a semiconductor device formed by a p-n junction, thereby forming a hole-electron pair. In the formed hole-electron pair, the electron moves to an n-type semiconductor layer and the hole moves to a p-type semiconductor layer, according to electric fields generated in the p-n junction part. As a result, electromotive force is generated between the p-type semiconductor layer and the n-type semiconductor layer. When a load is connected to electrodes formed on the two semiconductor layers, a current flows according to the generated electromotive force.

In the solar cell, a study based on a monocrystalline silicon was initially conducted, and a silicon-based solar cell based on a polycrystalline silicon and an amorphous silicon was developed. In addition, various solar cells such as a compound semiconductor such as CdTe. CuInSe₂, or the like, a dye-sensitized solar cell, an organic solar cell, and the like, have been developed to attempt to improve efficiency.

In addition to a technology of improving photoelectric conversion efficiency according to selection of the above-mentioned material, an attempt to improve the photoelectric conversion efficiency by changing a structure and adopting a new structure has been conducted. A typical technology is to increase a ratio of incident light by forming a surface roughness or a predetermined regular structure through selective etching in a region at which sunlight is incident. In these structures, an excessive etching process is introduced, such that a complicated manufacturing process is required.

Recently, an attempt to use a nitride semiconductor rather silicon as a photoactive layer has been conducted. A nitride semiconductor-based solar cell has a mechanism of absorbing sunlight by adjusting bandgaps of GaN(3.4 eV) and InN(0.7 eV). Since the nitride semiconductor-based solar cell has an advantage in that it may absorb most of the sunlight, many studies on the nitride semiconductor-based solar cell have been conducted. A thin film property should be secured, and a problem of adjusting a content of indium should be solved.

In addition, an attempt to form a surface concave-convex structure by an etching process has been conducted. However, there are still problems such as a complicated manufacturing process, deformation of a material of a thin film due to etching, and the like.

### DISCLOSURE

### Technical Problem

An object of the present invention is to provide a solar cell formed by growing a nitride semiconductor at an intended region.

Another object of the present invention is to provide a manufacturing method of a solar cell for accomplishing the above-mentioned object.

### Technical Solution

According to an exemplary embodiment of the present invention, there is provided a nitride semiconductor based solar cell, including: a first n-type nitride semiconductor layer formed on a substrate; a mask layer formed on the first n-type nitride semiconductor layer and having opening parts; second n-type nitride semiconductor layers formed while penetrating through the opening parts from the first n-type nitride semiconductor layer and having a shape in which they protrude in a hexagonal pyramid shape; photoactive layers formed on the second n-type nitride semiconductor layers; p-type nitride semiconductor layers formed on the photoactive layers; a transparent electrode formed on the p-type nitride semiconductor layers; a cathode formed on the transparent electrode; and an anode formed on an exposed surface of the first n-type nitride semiconductor layer.

According to another exemplary embodiment of the present invention, there is provided a manufacturing method of a nitride semiconductor based solar cell, including: sequentially forming a first n-type nitride semiconductor layer and a mask layer on a substrate; patterning the mask layer to form opening parts partially exposing a surface of the first n-type nitride semiconductor layer; forming second n-type nitride semiconductor layers penetrating through the opening parts of the mask layer based on the exposed first n-type nitride semiconductor layer and protruding in a hexagonal pyramid shape; sequentially forming photoactive layers and p-type nitride semiconductor layers on the second n-type nitride semiconductor layers protruding in the hexagonal pyramid shape; forming a transparent electrode on the p-type nitride semiconductor layers and the mask layer; and forming a cathode and an anode on the transparent electrode and the first n-type nitride semiconductor layer, respectively.

### Advantageous Effects

According to the exemplary embodiment of the present invention described above, the mask layer includes the opening parts formed at predetermined intervals. The second n-type nitride semiconductor layers are formed based on the first n-type nitride semiconductor layer exposed through the opening parts, penetrate through the opening parts, and have the hexagonal pyramid shape from a plane formed by the opening parts. In addition, the photoactive layers and the p-type nitride semiconductor layers are sequentially formed based on the formed second n-type nitride semiconductor layers. Therefore, the entire area of the photoactive layer receiving incident light is increased. Therefore, photoelectric conversion efficiency may be improved.

### DESCRIPTION OF DRAWINGS

FIG. 1 is a cross-sectional view showing a solar cell according to an exemplary embodiment of the present invention;

FIGS. 2 to 7 are cross-sectional views for describing a manufacturing method of a solar cell according to the exemplary embodiment of the present invention; and

FIG. 8 is an image showing a second n-type nitride semiconductor layer formed according to the exemplary embodiment of the present invention.

### BEST MODE

The present invention may be variously modified and have several forms. Therefore, specific exemplary embodiments of the present invention will be illustrated in the accompanying drawings and be described in detail in the present specification. However, it is to be understood that the present invention is not limited to a specific disclosed form, but includes all modifications, equivalents, and substitutions without departing from the scope and spirit of the present invention. In describing the respective drawings, similar components will be denoted by similar reference numerals.

Unless indicated otherwise, it is to be understood that all the terms used in the specification including technical and scientific terms have the same meaning as those that are understood by those who skilled in the art. It must be understood that the terms defined by the dictionary are identical with the meanings within the context of the related art, and they should not be ideally or excessively formally defined unless the context clearly dictates otherwise.

Hereinafter, exemplary embodiments of the present invention will be described in more detail with reference to the accompanying drawings.

### Exemplary Embodiment

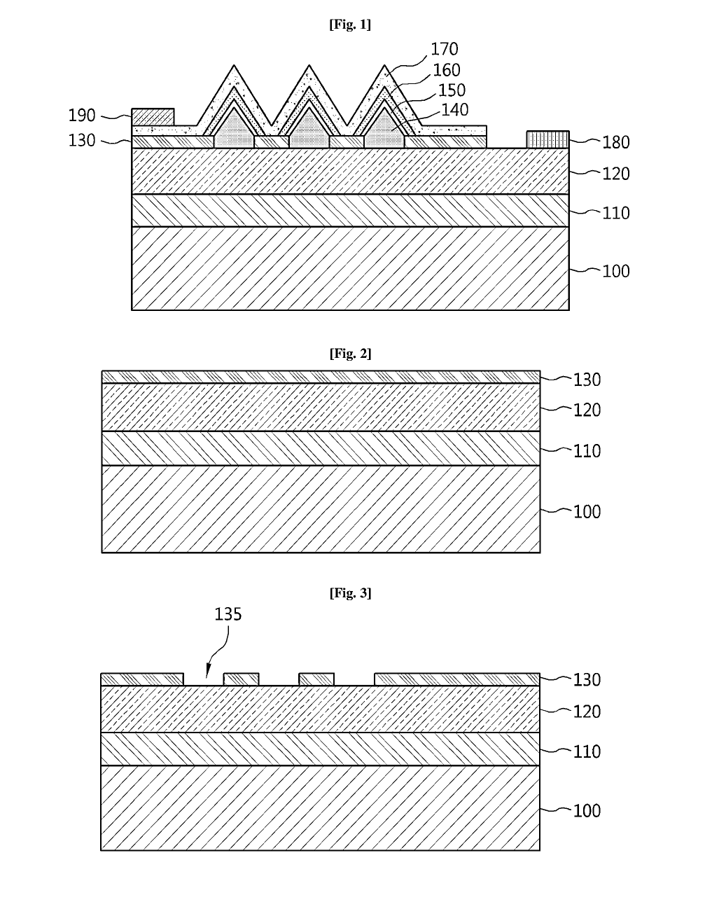

FIG. 1 is a cross-sectional view showing a solar cell according to an exemplary embodiment of the present invention.

Referring to FIG. 1, a buffer layer 110 is formed on a substrate 100. The formed buffer layer 110 may include GaN, AlN, or ZnO. The buffer layer 110 is provided in order to minimize distortion of a crystal structure due to lattice mismatch between a subsequently formed film and the substrate 100. Therefore, a material of the buffer layer 110 may be variously selected according to a kind of substrate 100. Particularly, it is preferable that in the case in which the substrate 100 is made of sapphire, the buffer layer 110 includes GaN.

A first n-type nitride semiconductor layer 120 is formed on the buffer layer 110. Second n-type nitride semiconductor layers 140 are formed on the first nitride semiconductor layer 120. The second n-type nitride semiconductor layers 140 are formed based on the first nitride semiconductor layer 120. Therefore, it is preferable that the second n-type nitride semiconductor layers 140 have substantially the same chemical composition as that of the first nitride semiconductor layer 120. Particularly, the second n-type nitride semiconductor layers 140 have a shape in which they protrude at specific regions. That is, the second n-type nitride semiconductor layers 140 have a shape in which they protrude from a mask layer 130 covering an upper portion of the first n-type nitride semiconductor layer 120.

In addition, the mask layer 130 has opening parts formed at predetermined regions, and the second n-type nitride semiconductor layers 140 protrude from the formed opening parts. A protrusion portion of the second n-type nitride semiconductor layer 140 has a hexagonal pyramid shape. In addition, an anode 180 is formed at a region on the first n-type nitride semiconductor layer 120 at which the mask layer 130 is partially removed.

Photoactive layers 150 are formed on the second n-type nitride semiconductor layers 140 protruding from the mask layer 130. It is preferable that the photoactive layer 150 has a multi-quantum well structure. That is, the photoactive layer 150 has a structure in which barrier layers and well layers are alternately formed. Light incident through the photoactive layer 150 forms an electron-hole pair. In addition, the photoactive layer 150 may also have a quantum dot structure and be formed of an intrinsic nitride semiconductor in which a dopant is excluded.

P-type nitride semiconductor layers 160 are formed on the photoactive layers 150. The p-type nitride semiconductor layer 160 becomes a passage through the hole formed in the photoactive layer 150 moves. In addition, it is preferable that in the case in which the first n-type nitride semiconductor layer 120 includes GaN, the second n-type nitride semiconductor layer 140, the photoactive layer 150, or the p-type nitride semiconductor layer 160 includes GaN.

Next, a transparent electrode 170 is formed on the p-type nitride semiconductor layers 160. The transparent electrode 170 may be made of any material having a high light transmittance and conductivity. The transparent electrode 170 is formed in an aspect in which it covers the second n-type nitride semiconductor layers 140 protruding through the opening parts of the mask layer 130, the photoactive layers 150, and the p-type nitride semiconductor layers 160.

A cathode 190 is formed at a specific region on the transparent electrode 170. Particularly, it is preferable that the cathode 190 is formed at a flat region in a portion except for a region protruding through the opening part of the mask layer 130.

As described above, the second n-type nitride semiconductor layer 140 having the hexagonal pyramid shape protrudes, such that the photoactive layer 150 and the p-type nitride semiconductor layer 160 have a shape in which they protrude. Therefore, an area in which sunlight is incident may be increased, and photoelectric conversion efficiency may be generally improved.

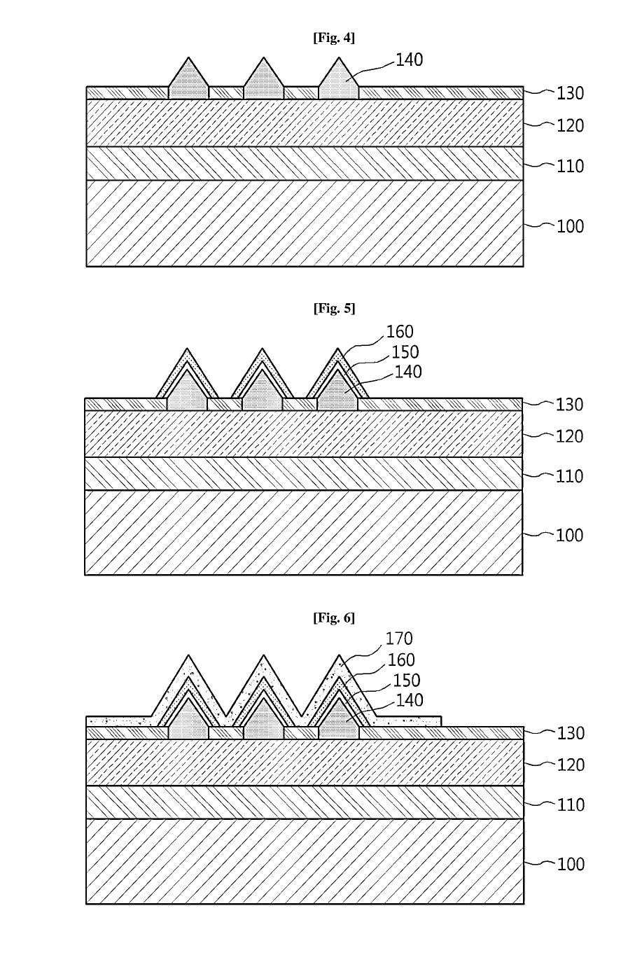

FIGS. 2 to 7 are cross-sectional views for describing a manufacturing method of a solar cell according to the exemplary embodiment of the present invention.

Referring to FIG. 2, the buffer layer 110, the first n-type nitride semiconductor layer 120, and the mask layer 130 are sequentially formed on the substrate 100.

First, it is preferable that the substrate 100 has a crystal structure that is the same as or similar to that of the buffer layer 110 or the first n-type nitride semiconductor layer 120 to be formed later thereon. Therefore, in the case in which the buffer layer 110 or the first n-type nitride semiconductor layer 120 has a hexagonal system structure, the substrate 100 may also have a hexagonal system structure. Therefore, in the case in which the buffer layer 110 includes GaN, AlN, or ZnO, the substrate 100 may be made of sapphire, GaN, ZnO, or ZnSe. Particularly, it is preferable that the substrate 100 is made of sapphire, and the buffer layer 110 may include GaN, AlN, or ZnO. The buffer layer 110 is formed by chemical vapor deposition or physical vapor deposition. Particularly, it is preferable that the buffer layer 110 is formed by a metal organic chemical vapor deposition (MOCVD) method. It is preferable that the buffer layer 110 has a thickness of 20 nm to 1 μm. In the case in which the buffer layer 110 has a thickness less than 20 nm, it is difficult to secure crystallinity at the time of forming an upper film, and in the case in which the buffer layer 110 has a thickness exceeding 1 μm, an excessive process time is required.

The first n-type nitride semiconductor layer 120 is formed on the buffer layer 110. A group IV element is used as a dopant in order to have an n-type conductivity. Particularly, Si is used as the dopant. In addition, the first n-type nitride semiconductor layer 120 may be formed by a metal organic chemical vapor deposition method. The formed first n-type nitride semiconductor layer 120 includes a crystal of a hexagonal system. Therefore, the first n-type nitride semiconductor layer 120 may be formed of a single crystal and be formed in an aspect in which it has a defect in a partial region. The formed first n-type nitride semiconductor layer 120 is used as a transfer layer of electrons generated by incidence of the sunlight.

In addition, the first n-type nitride semiconductor layer 120 has a thickness of 10 to 50 μm. In the case in which the first n-type nitride semiconductor layer 120 has a thickness less than 10 μm, it is difficult to secure sufficient crystallinity, and in the case in which the first n-type nitride semiconductor layer 120 has a thickness exceeding 50 μm, a process time is excessive, and loss in an electron transfer phenomenon occurs.

Next, the mask layer 130 is formed on the first n-type nitride semiconductor layer 120. The mask layer 130, which is an insulator, may be made of any material having an etching selectivity with respect to the first n-type nitride semiconductor layer 120 disposed therebeneath. For example, a silicon oxide may be used as a material of the mask layer 130. The mask layer 130 is formed by chemical vapor deposition or physical vapor deposition.

Referring to FIG. 3, opening parts 135 having a regular pitch are formed by selectively etching the mask layer 130 formed in FIG. 2. The opening parts 135 are formed, such that a partial region of the first n-type nitride semiconductor layer 120 is exposed. The opening parts 135 may be formed by a general photolithography process and an etching process.

That is, a photo-resist is applied onto the mask layer 130 and patterning is performed to form photo-resist patterns. Then, when etching is performed using the photo-resist patterns as an etching mask, the mask layer 130 having the opening parts 135 may be formed. A plurality of opening parts 135 are provided in the mask layer 130 and have a regular arrangement. In addition, it is preferable that the respective opening parts 135 have a width set to 1 to 5 μm and have a circular or rectangular shape. In the case in which the opening part 135 has a width less than 1 μm, since the second n-type nitride semiconductor layers 140 formed while penetrating through the opening parts 135 may not have a sufficient height, it is difficult to expect improvement of efficiency. In addition, in the case in which the opening part 135 has a width exceeding 5 μm, a sufficient number of second n-type nitride semiconductor layers 140 may not be secured on the substrate.

In addition, the opening parts 135 of the mask layer 130 may be formed by various methods such as a nano imprinting process, laser interference lithography, hologram lithography, and the like.

Referring to FIG. 4, the second n-type nitride semiconductor layers 140 are formed on a structure of FIG. 3. The second n-type nitride semiconductor layer 140 has selectivity in growth of a film. That is, the second n-type nitride semiconductor layer 140 has a feature that it is grown based on a film having a crystal structure that is the same as or similar to that thereof and disposed therebeneath. Particularly, in the case in which the second n-type nitride semiconductor layer 140 is formed by a metal organic chemical vapor deposition method, an aspect of growth of the second n-type nitride semiconductor layer 140 is detected according to a material of the film disposed therebeneath. For example, the second n-type nitride semiconductor layers 140 are not grown on the mask layer 130 having an amorphous structure such as a silicon oxide, but are grown only on the first n-type nitride semiconductor layer 120 exposed through the opening parts. Therefore, the second n-type nitride semiconductor layers 140 are grown through penetrating through the opening parts of the mask layer 130.

Particularly, the second n-type nitride semiconductor layer 140 is grown in an aspect in which it is completely buried in the opening part of the mask layer 130 and is then grown in a hexagonal pyramid shape. This may be implemented by controlling a process temperature, a concentration of source gas, or a growth speed in the metal organic chemical vapor deposition method. In addition, in the case in which the opening parts of the mask layer 130 has a regular arrangement in which they have the same pitch, the hexagonal pyramids of the second n-type nitride semiconductor layers 140 formed while penetrating through the respective opening parts have the same shape as each other. That is, the hexagonal pyramids of the second n-type nitride semiconductor layers 140 have the same thickness and have substantially the same height.

That is, in the case in which a general metal organic chemical vapor deposition method is used in FIG. 3, the second n-type nitride semiconductor layers 140 are not grown on the mask layer 130, but are selectively grown while penetrating through the opening parts provided in the mask layer 130.

Referring to FIG. 5, the photoactive layers 150 and the p-type nitride semiconductor layers 160 are sequentially formed on the second n-type nitride semiconductor layers 140 formed in FIG. 4.

That is, the photoactive layers 150 having crystallinity are formed on the second n-type nitride semiconductor layers 140 protruding in a hexagonal pyramid shape from a plane formed by the mask layer 130. The photoactive layer 150 may have a quantum dot structure, an intrinsic semiconductor structure, or a multi-quantum well structure.

Particularly, in the case in which the photoactive layer 150 has the multi-quantum well structure, it has an aspect in which barrier layers and well layers are alternately formed. The barrier layer and the well layer are determined according to a content ratio of an indium element. It is preferable that in the case in which the photoactive layer 150 is formed in the multi-quantum well structure, the barrier layer has a thickness of 5 to 15 nm and the well layer has a thickness of 1.5 to 3.5.nm. In addition, the thicknesses of the barrier layer and the well layer may be adjusted according to an amount and a wavelength of light transmitted to the photoactive layer 150.

The photoactive layer 150 has the same crystal structure as that of the second n-type nitride semiconductor layer 140 disposed therebeneath and has selectivity in growth. For example, in the case in which the second n-type nitride semiconductor layer 140 includes GaN, the photoactive layer 150 may include InGaN. In addition, the photoactive layers 150 are not formed on the mask layer 130 except for on the protruding second n-type nitride semiconductor layer 140. This is due to a phenomenon that a crystal structure of the photoactive layer 150 depends on orientation of a film disposed beneath the photoactive layer 150. That is, the photoactive layers 150 having the crystallinity are not grown on the mask layer 130 made of an amorphous silicon oxide.

Then, the p-type nitride semiconductor layers 160 are formed on the photoactive layers 150. In the p-type nitride semiconductor layer 160, a group II element, preferably, Mg is used as a dopant. The p-type nitride semiconductor layer 160 also has selectivity in growth, similar to the photoactive layer 150. Therefore, the p-type nitride semiconductor layer 160 has a feature that it is grown only on the photoactive layer 150. It is preferable that a thickness of the p-type nitride semiconductor layer 160 is set to 100 to 300 nm. In the case in which the thickness of the p-type nitride semiconductor layer 160 is less than 100 nm, it is difficult to secure sufficient crystallinity, and in the case in which the thickness of the p-type nitride semiconductor layer 160 exceeds 300 nm, it is difficult for a hole to be smoothly moved.

However, materials configuring the photoactive layers 150 and the p-type nitride semiconductor layers 160 may remain on the mask layer 130 except for the protruding second n-type nitride semiconductor layers 140. These materials may be easily removed by cleaning, wet etching, or the like.

Referring to FIG. 6, the transparent electrode 170 is formed on the structure shown in FIG. 5.

Particularly, it is required that the transparent electrode 170 has a predetermined transmittance and electrical conductivity. Therefore, it is preferable that an indium tin oxide (ITO) is used as a material of the transparent electrode 170. However, in another exemplary embodiment of the present invention, various materials such as an indium zinc oxide (IZO), and the like, in addition to the ITO, may be selected

The transparent electrode 170 is applied over the entire surface of the structure shown in FIG. 5 by a general deposition method. Therefore, the transparent electrode 170 is formed over the mask layer 130 and the p-type nitride semiconductor layer 160. In addition, the transparent electrode 170 is patterned by a general photolithography process. Therefore, the mask layer 130 is exposed at a predetermined region at which the anode 180 shown in FIG. 1 is formed.

Referring to FIG. 7, etching is performed on the mask layer 130 using the transparent electrode 170 shown in FIG. 6 as an etching mask. An upper surface of the first n-type nitride semiconductor layer 120 is exposed in a region except for a region covered by the transparent electrode 170 through the etching.

Next, the anode 180 and the cathode 190 are formed on the exposed upper surface of the first n-type nitride semiconductor layer 120 and the transparent electrode 170, respectively. The anode 180 and the cathode 190 are formed by a general electrode process using a hard mask. For example, the anode 180 may include Cr/Au or Ti/Al/Au. In addition, the cathode 190 may include Cr/Au or Ni/Au.

Particularly, it is preferable the anode 180 and the cathode 190 forming an electrode pad is formed on a flat surface of a film disposed therebeneath. For example, it is preferable that the cathode 190 is formed on a flat surface of the transparent electrode 170 and the anode 180 is formed on a flat surface of the first n-type nitride semiconductor layer 120 exposed by the etching.

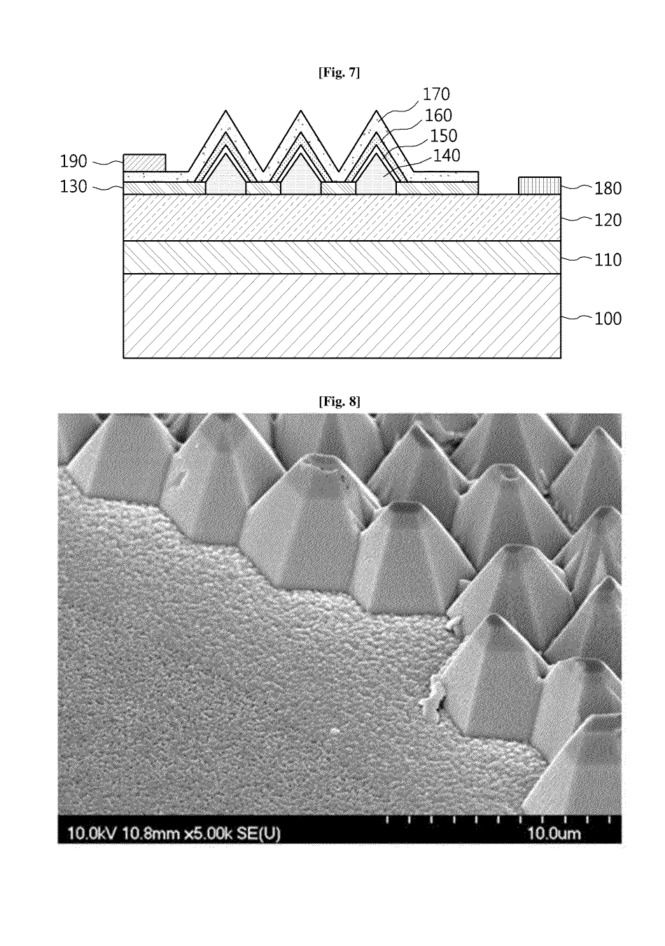

FIG. 8 is an image showing a second n-type nitride semiconductor layer formed according to the exemplary embodiment of the present invention.

Referring to FIG. 8, the second n-type nitride semiconductor layers having the hexagonal pyramid shape are formed while penetrating through the opening parts of the mask layer made of the silicon oxide. The hexagonal pyramid shape may be formed by a general MOCVD process. For example, rather than forming a flat film through growth of a side surface, a vertical growth factor is allowed to be more excellent than a horizontal growth factor, thereby making it possible to form a shape protruding from a surface.

Through the above-mentioned process, the solar cell in which the n-type nitride semiconductor layer has the hexagonal pyramid shape and the photoactive layer and the p-type nitride semiconductor layer are formed according to the hexagonal pyramid shape. Therefore, an area in which sunlight is incident may be increased, and photoelectric conversion efficiency may be improved.

[Detailed Description of Main Elements]

| | |
|---|---|
| 100: Substrate | 110: Buffer layer |
| 120: First n-type nitride semiconductor layer | 140: Second n-type |
| 130: Mask layer | nitride semiconductor layer |
| 150: Photoactive layer | 160: P-type nitride |
| 170: Transparent electrode | semiconductor layer |

1. A nitride semiconductor based solar cell, comprising:
a first n-type nitride semiconductor layer formed on a substrate;
a mask layer formed on the first n-type nitride semiconductor layer and having opening parts;
second n-type nitride semiconductor layers formed while penetrating through the opening parts from the first n-type nitride semiconductor layer and having a shape in which they protrude in a hexagonal pyramid shape;
photoactive layers formed on the second n-type nitride semiconductor layers;
p-type nitride semiconductor layers formed on the photoactive layers;
a transparent electrode formed on the p-type nitride semiconductor layers;
a cathode formed on the transparent electrode; and
an anode formed on an exposed surface of the first n-type nitride semiconductor layer.

2. The nitride semiconductor based solar cell of claim 1, wherein the first n-type nitride semiconductor layer, the second n-type nitride semiconductor layer, the p-type nitride semiconductor layer, or the photoactive layer includes GaN.

3. The nitride semiconductor based solar cell of claim 1, wherein the second n-type nitride semiconductor layer has the same crystal structure as that of the first n-type nitride semiconductor layer.

4. The nitride semiconductor based solar cell of claim 1, wherein the second n-type nitride semiconductor layer has the same chemical composition as that of the first n-type nitride semiconductor layer.

5. The nitride semiconductor based solar cell of claim 1, wherein the photoactive layer has a multi-quantum well structure according to adjustment of a content of indium.

6. The nitride semiconductor based solar cell of claim 1, wherein the photoactive layer is formed according to the hexagonal pyramid shape of the second n-type nitride semiconductor layer.

7. The nitride semiconductor based solar cell of claim 6, wherein the p-type nitride semiconductor layer is formed according to the hexagonal pyramid shape of the second n-type nitride semiconductor layer.

8. A manufacturing method of a nitride semiconductor based solar cell, comprising:
sequentially forming a first n-type nitride semiconductor layer and a mask layer on a substrate;
patterning the mask layer to form opening parts partially exposing a surface of the first n-type nitride semiconductor layer;
forming second n-type nitride semiconductor layers penetrating through the opening parts of the mask layer based on the exposed first n-type nitride semiconductor layer and protruding in a hexagonal pyramid shape;
sequentially forming photoactive layers and p-type nitride semiconductor layers on the second n-type nitride semiconductor layers protruding in the hexagonal pyramid shape;
forming a transparent electrode on the p-type nitride semiconductor layers and the mask layer; and
forming a cathode and an anode on the transparent electrode and the first n-type nitride semiconductor layer, respectively.

9. The manufacturing method of claim 8, wherein the forming of the transparent electrode includes:
applying the transparent electrode over the mask layer and the entire surface of the p-type nitride semiconductor layer; and
etching a partial region of the transparent electrode formed on the mask layer in which the opening parts are not formed to expose a partial region of the mask layer.

10. The manufacturing method of claim 8, further comprising, after the forming of the transparent electrode, etching the exposed mask layer using the transparent electrode as an etching mask to expose a portion of the first n-type nitride semiconductor layer.

11. The manufacturing method of claim 10, wherein the anode is formed on the exposed first n-type nitride semiconductor layer, and the cathode is formed on the transparent electrode.

12. The manufacturing method of claim 11, wherein the cathode is formed on a flat surface of the transparent electrode.
